(19) United States
(12) Patent Application Publication
(10) Pub. No.: US 2026/0156843 A1
(43) Pub. Date: Jun. 4, 2026

(54) INPUT RESISTANCE FOR COMPACT PACKAGING OF SEMICONDUCTOR DIES

(71) Applicant: SEMICONDUCTOR COMPONENTS INDUSTRIES, LLC, Scottsdale, AZ (US)

(72) Inventor: Seungwon IM, Bucheon (KR)

(73) Assignee: SEMICONDUCTOR COMPONENTS INDUSTRIES, LLC, Scottsdale, AZ (US)

(21) Appl. No.: 18/965,910

(22) Filed: Dec. 2, 2024

(51) Int. Cl. H01L 23/00; H01L 23/538; H01L 25/065; H01L 25/16

(52) U.S. Cl. CPC H10D 1/47; H10W 90/00; H10W 70/60; H10W 70/611; H10W 72/5434; H10W 72/5473; H10W 90/753; H10W 90/754

(57) ABSTRACT

Apparatuses using on-pad input resistance for compact packaging of semiconductor dies are described herein, as well as methods for constructing such apparatuses and systems and devices that use them. An example apparatus includes a substrate, a first semiconductor die disposed on the substrate and implementing a first field-effect transistor with a gate terminal accessible by a first gate pad, and a second semiconductor die disposed on the substrate and implementing a second field-effect transistor with a gate terminal accessible by a second gate pad. A conductive element is configured to electrically couple the first gate pad and the second gate pad to a shared gate node with a first resistor coupled to the first gate pad (between the conductive element and the first gate pad) and with a second resistor coupled to the second gate pad (between the conductive element and the second gate pad).

### BACKGROUND

Packaging plays a critical role in ensuring the proper function, reliability, and ease of use of electronic components. Proper packaging of electronic components may serve various roles. For example, one function of a package may be to protect a delicate semiconductor die inside the package from physical damage, contamination, electrostatic discharge (ESD), etc., since these threats could render the component inoperable if the die is not properly protected. Similarly, the package may also provide a barrier against moisture and exposure to other environmental elements that could lead to degradation and malfunction of the component. Another role of the package may be to facilitate electrical connections between the internal circuitry of the component and external circuitry (e.g., of a circuit board to which the electronic component is coupled, etc.). For example, metal pins, leads, bumps, and other such features may allow for the electrical component to be soldered onto or otherwise connected to a printed circuit board. Heat dissipation may also be provided by packaging that is configured to facilitate heat transfer away from operational elements of the component (e.g., the semiconductor die inside the device package).

### SUMMARY

Power electronics are configured to process relatively large voltages and currents for automotive, industrial, and other high-power applications and use cases. To handle particularly large amounts of power, multiple transistors (e.g., power field-effect transistors (FETs) or other types of transistors) may be connected in parallel to effectively share the load of large current that is to be switched or otherwise manipulated. In this type of scenario, it can be a challenge to match the current handled by each of the parallel components. As such, a particular gate resistance may be implemented at the gate of each parallel transistor in a particular circuit to help balance the current. To avoid enlarging the footprint of the circuit packaging by connecting surface-mount gate resistors to each parallel transistor in a given circuit, systems and methods described herein utilize resistors that are disposed directly on pads of semiconductor dies implementing power transistors (e.g., on gate pads of power FETs or the like). In this way, proper current balancing may be achieved while compact packaging for circuitry implementing the parallel transistors may simultaneously be provided. For example, an automotive power inverter device applying on-pad input resistance principles described herein may provide effective current balancing between parallel transistors while also providing a compact form factor, correspondingly reduced complexities and costs, and other benefits described herein.

As one example implementation, an apparatus (e.g., an electronic component such as a packaged semiconductor device) may include: 1) a substrate; 2) a first semiconductor die disposed on the substrate and implementing a first field-effect transistor with a gate terminal accessible by a first gate pad; 3) a second semiconductor die disposed on the substrate and implementing a second field-effect transistor with a gate terminal accessible by a second gate pad; 4) a conductive element configured to electrically couple the first gate pad and the second gate pad to a shared gate node; 5) a first resistor coupled to the first gate pad between the conductive element and the first gate pad; and 6) a second resistor coupled to the second gate pad between the conductive element and the second gate pad.

As another example implementation, a power inverter device (e.g., an automotive power inverter for an electric or hybrid vehicle, etc.) may include a heatsink and a plurality of power inverter apparatuses installed on the heatsink. This plurality of power inverter apparatuses may include a power inverter apparatus comprising: 1) a substrate, 2) a first semiconductor die disposed on the substrate and implementing a first field-effect transistor with a gate terminal accessible by a first gate pad, 3) a second semiconductor die disposed on the substrate and implementing a second field-effect transistor with a gate terminal accessible by a second gate pad, 4) a conductive element configured to electrically couple the first gate pad and the second gate pad to a shared gate node, 5) a first resistor coupled to the first gate pad between the conductive element and the first gate pad, and 6) a second resistor coupled to the second gate pad between the conductive element and the second gate pad.

As another example implementation, a method (e.g., a manufacturing process for fabricating an apparatus or device such as described above) may include: 1) preparing a substrate; 2) coupling a first semiconductor die with the substrate, the first semiconductor die implementing a first field-effect transistor with a gate terminal accessible by a first gate pad; 3) coupling a second semiconductor die with the substrate, the second semiconductor die implementing a second field-effect transistor with a gate terminal accessible by a second gate pad; 4) coupling a first resistor to the first gate pad and a second resistor to the second gate pad; and 5) coupling a conductive element with the first resistor on the first gate pad and with the second resistor on the second gate pad.

Each of the preceding example implementations will be understood to be illustrative of the types of implementations that are consistent with the following description. It will be understood that these examples are not intended to be limiting and that any of the aspects mentioned above or described herein may be used with any of the implementations in accordance with principles described herein. The details of these and other implementations are set forth in the accompanying drawings and the description below. Other features will also be apparent from the following description, drawings, and claims.

### BRIEF DESCRIPTION OF THE DRAWINGS

FIG. 1 shows different views of an illustrative implementation of an apparatus featuring on-pad input resistance for compact packaging of semiconductor dies in accordance with principles described herein.

FIG. 2 shows certain aspects of an illustrative implementation of a power inverter apparatus featuring on-pad input resistance for compact packaging of semiconductor dies in accordance with principles described herein.

FIG. 3 shows additional views of certain aspects of the illustrative power inverter apparatus of FIG. 2 in accordance with principles described herein.

FIG. 4A illustrates certain contrasting aspects between a conventional power inverter apparatus and the illustrative power inverter apparatus of FIG. 2 in accordance with principles described herein.

FIG. 4B illustrates certain contrasting aspects between another conventional power inverter apparatus and the illustrative power inverter apparatus of FIG. 2 in accordance with principles described herein.

FIG. 4C illustrates additional contrasting aspects between the conventional power inverter apparatus of FIG. 4B and the illustrative power inverter apparatus of FIG. 2 in accordance with principles described herein.

FIG. 5 shows different views of a power inverter apparatus integrated with a leadframe in accordance with principles described herein.

FIG. 6 shows certain aspects of a packaged power inverter apparatus encapsulated in a molding compound in accordance with principles described herein.

FIG. 7 shows certain aspects of an illustrative power inverter device featuring a plurality of power inverter apparatuses installed on a heatsink in accordance with principles described herein.

FIG. 8 shows an illustrative method for constructing an apparatus featuring on-pad input resistance for compact packaging of semiconductor dies in accordance with principles described herein.

### DETAILED DESCRIPTION

Principles described herein relate to input resistance (e.g., on-pad input resistance) for compact packaging of semiconductor dies. For instance, various implementations of these principles include electronic components, apparatuses, devices, systems, and so forth, along with methods, processes, and techniques for constructing the same.

Many electronics applications involve relatively small voltages and currents, allowing small, and even microscopic, electronic components to be used to process and manipulate the voltages and currents. Other electronics applications, however, may involve larger voltages and currents. For example, applications and use cases in the automotive space (e.g., electric vehicles (EVs), hybrid vehicles, etc.) and/or in other industrial contexts with large-scale machinery may employ electronics harnessing large amounts of power requiring components that are configured accordingly. To properly process and manipulate these larger voltages and currents, power electronics such as power field-effect transistors (FETs) and/or other types of power transistors may be employed.

In certain cases, a sufficient amount of current may be in play that a function that could otherwise be performed by a singular component (e.g., a singular power transistor) may instead be performed by a plurality of such components. For instance, several power FETs could be connected in a manner that allows the transistors to share the current load of the circuit (e.g., a half-bridge or full-bridge circuit that plays a part within power inverter circuitry, as one example) and essentially act as one unified transistor in the circuit.

A significant technical problem may arise, however, when multiple distinct transistors are configured to interoperate to perform a singular function in this way. This challenge relates to balancing the current load between parallel transistors (i.e., reducing a deviation of how much current flows through the different transistors) and ensuring an equal distribution (or other desired or predetermined distribution ratio) of current between distinct transistors in the circuit. If different FETs are driven to different extents due to different voltages being presented at their respective gate terminals, certain FETs could conduct significantly more current than others, thereby leading to various additional technical problems such as inefficiency, thermal issues, runaway currents (which could lead to components being used outside of operating parameters), shortened operational lifetimes, and so forth.

At least one technical solution described herein for avoiding and/or otherwise mitigating these technical problems involves applying gate resistance to each gate terminal of each FET in a plurality of parallel FETs being used in a circuit. Conventional ways of adding gate resistance to discrete power FETs, however, may introduce additional technical problems. For example, given a device package that includes several parallel transistors (e.g., FETs of a power inverter device whose gate terminals are all to be driven by a same node or signal), the transistors may be implemented as individual semiconductor dies that are all disposed on a unified substrate of the device package. For each discrete component (e.g., surface mount resistor, etc.) associated with each semiconductor die within a device, a substrate of the device would generally need to be larger to accommodate the discrete component and any on-substrate routing associated therewith (e.g., pads and traces on the substrate, clearances between conductive pads and traces, etc.).

While this increase in area may be suitable for certain devices and/or under certain circumstances, it may be costly and otherwise undesirable in other respects. For example, for device package designs in which compact and efficient packages (i.e., packages that are as small and unimposing in size, weight, shape, etc., as possible) are desired, additional discrete components (e.g., surface mount parts disposed on the substrate) work against design targets. More particularly, packaging for a device tends to become less compact and efficient as gate resistors for discrete semiconductor dies implementing FETs within the device are added to the design.

Technical solutions described herein address these technical problems in a way that allows for the desired gate resistances to be included (to therefore assist with current balancing within the circuit, etc.) while not requiring additional substrate area that would make the device packaging less compact (i.e., without making the overall size or footprint of apparatus larger or less efficient than it might otherwise be). For example, as detailed below, implementations described herein use on-pad input resistance for gate resistance of semiconductor dies such as discrete FET dies. In place of a surface mount resistor disposed near the die and connected in-series with the gate of the FET, for example, a leadless resistor component may be mounted directly on a gate pad of a semiconductor die with a gate interconnect (e.g., a wire connecting all the gates of the various FETs) connected to the resistor. As will be illustrated and described, a gate pad may provide access to the FET's gate, such that mounting a leadless resistor right on the pad allows for all the benefits of having the gate resistor but without any of the drawbacks and overhead described above to be associated with surface mount resistors and their placement issues, interconnection issues, and so forth.

Technical effects of these solutions involve both functional benefits of gate resistors (i.e., the improved current sharing and current balancing that has been described, power savings, increased efficiencies and effectiveness of the device, etc.) as well as package-related benefits arising from the reduction of the substrate size (e.g., more compact packaging for reduced costs and complexity, more flexible designs, etc.). In other words, technical solutions provided herein use stackable gate interconnections to support effective and efficient current balancing without compromise to other objectives such as those relating to compact packaging.

While principles described herein may be advantageous in a variety of contexts, applications, and use cases, a concrete example of a power inverter apparatus will be used as a running example throughout the following description. As will be described, power inverters may be useful in various contexts such as in converting direct current (DC) power from a battery of an electric vehicle into alternating current (AC) power that can be used to perform the mechanical work involved in propelling the vehicle. As such, and as will be described in more detail below, automotive inverter devices described herein may apply on-pad input resistance principles to provide effective current balancing (i.e., reducing current deviations) between parallel transistors while also providing compact form factors and other benefits described herein.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. On-pad input resistance for compact packaging of semiconductor dies in accordance with principles described herein may result in any or all of the technical benefits mentioned above, as well as various additional technical benefits that will be described and/or made apparent below.

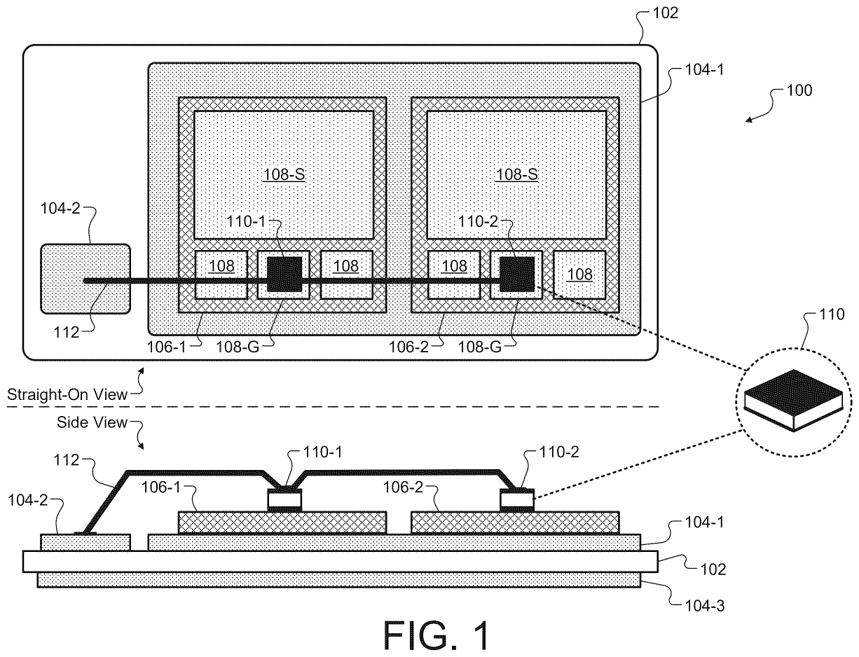

FIG. 1 shows different views of an illustrative implementation of an apparatus featuring on-pad input resistance for compact packaging of semiconductor dies in accordance with principles described herein. More particularly, a “Straight-On View” and a “Side View” of certain elements of an apparatus 100 are shown in FIG. 1 to include: 1) a substrate 102; 2) conductive portions 104-1 and 104-2 on the substrate 102; 3) a first semiconductor die 106-1 and a second semiconductor die 106-2, each disposed on the substrate 102 and including various pads 108; 4) a first resistor 110-1 associated with semiconductor die 106-1 and a second resistor 110-2 associated with semiconductor die 106-2; and 5) a conductive element 112 electrically coupling particular elements of the semiconductor dies and the substrate, as will be described. It will be understood that, while the illustrated elements may be among those most relevant to implementations of on-pad input resistance for compact packaging of semiconductor dies described herein, there may be a variety of additional and/or alternative elements (elements not shown in FIG. 1) that could be included in this implementation of apparatus 100, in other implementations of apparatus 100 described in this paper, and in still other implementations of apparatus 100 not explicitly illustrated in this paper but that accord with principles described herein. Each of the illustrated elements will now be described in more detail.

Apparatus 100 is shown to include substrate 102 having multiple portions including (in this example specifically) a first portion 104-1 and a second portion 104-2 that is electrically isolated from the first portion. Substrate 102 may may be implemented by a directed-bonded metal (DBM) substrate such as a direct-bonded copper (DBC) substrate or the like that employs layers of a conductor (e.g., a metal such as copper, etc.) on an insulative tile (e.g., a ceramic plate, etc.). This structure may be employed to facilitate electrical insulation between different the different portions 104-1 and 104-2, to distribute signals to various places (e.g., using signal traces, power or ground planes, etc.), to provide thermal management for the apparatus (e.g., due to high thermal conductivity of the conductor, which helps to dissipate heat), and so forth.

The ceramic plate (i.e., the unshaded white part) of substrate 102 includes a first side (e.g., the side that is visible in the Straight-On View and that is on top as the plate is oriented in the Side View) and a second side opposite the first side (e.g., the side that is not visible in the Straight-On View and that is on the bottom as the plate is oriented in the Side View). The first side of the ceramic plate may be direct-bonded to a first metal layer on a top or front side of substrate 102 and that is patterned in this example to include the different portions 104-1 and 104-2. The second side of the ceramic plate may then be direct-bonded to a second metal layer (illustrated to have a singular portion 104-3 in the Side View of FIG. 1) that is configured to facilitate heat transfer away from the apparatus (e.g., acting as a heat sink to dissipate heat from heat-generating elements of the apparatus that will be described below). In other examples of substrate 102, both the first side and the second side may be patterned to include various portions (e.g., traces, planes, etc.) or both sides may include a solid plane of metal without any such electrically isolated portions. Moreover, it will be understood that both sides of the substrate may help dissipate heat.

A DBM-based implementation of substrate 102 may offer various advantages for packaging apparatuses such as apparatus 100 and/or other apparatuses described herein. For example, this type of substrate 102 may be configured to handle relatively large currents and voltages due to efficient thermal management provided by the heat dissipation mentioned above. This may be useful for apparatuses such as power modules that generate and/or consume large amounts of power. For instance, apparatuses described herein could implement power inverters for use in power systems or electric vehicles, motor drives used for appliances or electric vehicles, and various other examples as may serve a particular implementation. Other example advantages that DBM-based implementations of substrate 102 may offer include improved reliability (since the direct-bonding process between the ceramic and metal layers may create a strong and reliable connection), reduced size and weight (since DBM substrates are relatively thin and lightweight compared to other packaging materials), and so forth.

In some implementations, a DBM substrate (e.g., a direct-bonded copper (DBC) substrate, etc.) may be used that includes an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, the DBM substrate can be formed by bonding one or more of the metal layers (e.g., the first metal layer, the second metal layer, etc.) to the insulating layer (e.g., a ceramic layer or the like). For example, the one or more metal layers may be bonded to the insulating layer using, for example, a high-temperature process.

In some implementations, the first metal layer and/or the second metal layer can be configured to function as a heatsink. In some implementations, the first metal layer and/or the second metal layer can be coupled to a heatsink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and so forth.

In some implementations, the DBM substrate can be, or can include, a direct bonded copper (DBC) substrate. In some implementations, such as in DBC substrate implementations, the first metal layer and/or the second metal layer may be implemented as copper layers.

Regardless of how substrate 102 is implemented (e.g., as a DBM substrate or otherwise), FIG. 1 shows that one portion 104-1 may be electrically isolated from another portion 104-2. For example, the shapes labeled as portions 104-1 and 104-2 may be understood to represent separate planes of direct-bonded metal on the insulator (e.g., ceramic tile) or, in other implementations, separate parts of a leadframe (which may be held together during the manufacturing process by tie bars or other such mechanisms that would later be removed and are not explicitly shown in FIG. 1). In this example, a same portion 104-1 of substrate 102 is shown to host both parallel semiconductor dies 106-1 and 106-2. In other examples, however, each semiconductor die could be implemented on a separately isolated portion, and other portions of substrate 102 forming pads and traces for other components could also be included. In this implementation, portion 104-2 is shown to connect to a conductive element 112 coupled to the gate pads of multiple semiconductor dies. As will be described, portion 104-2 may thus be associated with a particular circuit node (e.g., a shared gate node) such that the portion may be employed as a connection point for package leads (e.g., of a separate leadframe described below) and/or other conductive elements.

Semiconductor dies 106-1 and 106-2 are shown to be disposed on substrate 102 (both on the same portion 104-1 in this particular example). These dies may each implement a singular field-effect transistor (FET) such as a metal-oxide-semiconductor field-effect transistor (MOSFET), a junction field-effect transistor (JFET), or another suitable transistor. More particularly, in cases where apparatus 100 is intended for an application or use case involving large amounts of voltage and/or current (e.g., such as for automotive power inverter use cases described herein), each of the FETs implemented by first semiconductor die 106-1 and 106-2 may be power FETs (e.g., power MOSFETS) or other power transistors.

In some implementations, semiconductor dies 106-1 and 106-2 may each implement identical transistors or at least similar transistors fabricated using the same type of semiconductor. For example, the first semiconductor die 106-1 and the second semiconductor die 106-2 could both be silicon carbide (SiC) dies fabricated using a SiC semiconductor or could both be silicon (Si) dies fabricated using a Si semiconductor. In other implementations, the first semiconductor die 106-1 and the second semiconductor die 106-2 may be hybrid dies fabricated using different semiconductors. For example, semiconductor die 106-1 could be a silicon (Si) die fabricated using a Si semiconductor, while second semiconductor die 106-2 could be a silicon carbide (SiC) die fabricated using a SiC semiconductor.

In some implementations, one or more semiconductor dies (e.g., one or more semiconductor components) can be, or can include, a power semiconductor die. In some implementations, a semiconductor die may implement one or more transistors or a portion of a transistor or transistor-based circuit. For example, one or more of a MOSFET device, an IGBT, an IC, an inverter, a power conversion circuit, a bridge circuit, a fast recovery diode (FRDs), a diode, or the like could be implemented on a semiconductor die. In some implementations, a component implemented (or partially implemented) by one or more semiconductor dies can be used or included within an electrical vehicle (EV).

More than one semiconductor die can be included in the implementations described herein. In some implementations involving more than one semiconductor die, the different semiconductor dies can be fabricated using different semiconductor substrates (e.g., a silicon carbide (SiC) substrate, a silicon (Si) substrate, a gallium nitride (GaN) substrate, etc.). In other words, different semiconductor dies may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second semiconductor die, for example, by an electrical connection (e.g., a wire bond, an electrical clip, a joint, etc.) extending directly from the first die to the second die, or connected through a trace formed in the first conductive layer (e.g., a metal layer) of an electronic power substrate. The first of the plurality of semiconductor dies may be also connected to leadframe posts by electrical connections such as wire bonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices can be fabricated on the same substrate (such as a SiC substrate suitable for high power applications).

In some implementations, one or more semiconductor dies can be embedded within a layer (rather than surface mounted). For example, one or more semiconductor dies can be disposed within a recess or cavity of a layer (e.g., a substrate, a printed circuit board, a conductive layer, an insulating layer, etc.).

Each semiconductor die 106-1 and 106-2 is shown to include several pads 108 that serve as terminals (inputs/outputs) to the transistors that the dies implement. Depending on the type of transistor being implemented and its particular construction (e.g., layout, etc.), pads 108 may have various sizes, shapes, and arrangements. For purposes of this implementation and others described below, however, it will be assumed that each semiconductor die 106-1 and 106-2 implements a FET with at least a gate terminal, a source terminal, and a drain terminal. As indicated by letters in some of the reference labels in FIG. 1, the source terminal of each FET may be accessible by a respective source pad 108-S of the die, while the gate terminal of each FET may be accessible by a respective gate pad 108-G. Respective drain pads providing access to drains of each FETs are not shown in FIG. 1, but will be understood to be on a back side of the die so as to physically and electrically contact the conductive surface of portion 104-1 of substrate 102. Other pads of each die (e.g., pads labeled generically (without letters) as pads 108) may provide access to other terminals as may serve a particular implementation. For instance, one or more Kelvin sense pads may be electrically coupled to other terminals and configured to facilitate accurate measurements of voltage or current at various terminals of the power transistor.

Each of the semiconductor dies 106-1 and 106-2 (as well as other components described herein and components that may be included in apparatus 100 but are not shown in FIG. 1) may be physically and electrically coupled to substrate 102 and to other elements (e.g., to one another, to other components, to leads allowing external access to the dies, etc.) in any suitable way. As a few examples, electrical connections of apparatus 100 and other implementations described herein may be achieved by way of soldering, sintering, conductive adhesives, other suitable coupling techniques, and/or a combination of two or more of these.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder or solder material.

In some implementations, sintering can be or can include a process of fusing particles together into one solid mass by using, for example, a combination of pressure and/or heat that is applied without melting the materials. In some implementations, sintering can include making a material (e.g., a powdered sintering material) coalesce into a solid or porous mass by heating the material (as well as, in some cases, compressing the material) without liquefaction. In some implementations, materials that can be used for sintering include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder material, a sintering material (e.g., silver, copper), and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

Connections between various circuit elements (e.g., pads, terminals, leads, conductive portions of the substrate, etc.) may involve conductive elements (also referred to herein as conductive components) that themselves are attached to the circuit elements that are to be connected. For example, conductive elements can connect different pads of the semiconductor dies to one another, to other components within the apparatus (not shown), to leads that extend away from the apparatus to facilitate connection with external circuitry, and so forth. Conductive elements may be implemented in any manner as may serve a particular implementation. For instance, in some examples, these conductive elements could represent wires coupled to their respective elements by way of a wire bonding process or other suitable technique. In other examples, the conductive components could represent clips that electrically connect the elements shown. In still other examples, the conductive elements could represent direct physical and electrical connections whereby the components are physically attached to one another by way of a connection mechanism that provides the electrical connections (e.g., solder material, sintering material, conductive adhesive, etc.). In some cases, a combination of different types of conductive elements may be employed within the same package or within the same implementation. For instance, certain connections could use wire bonding while other connections could utilize clips or direct connections.

As one example, a conductive element 112 is shown in apparatus 100 to provide a connection between a shared gate node accessible by way of portion 104-2 (e.g., by a lead connected to portion 104-2, not shown in FIG. 1 but described in more detail below) and each of the respective gate pads 108-G of semiconductor dies 106-1 and 106-2. While this conductive element 112 may be illustrated and described as a wire, it will be understood that, in at least some of the implementations, the wire could be replaced with other conductive elements. For example, in some implementations, one or more wire bonds can be replaced with a conductive clip, which could itself be coupled to another component (e.g., an attach pad, a leadframe, a semiconductor die, etc.) using, for example, a solder (e.g., a soldering process), a sintered coupling (e.g., a sintering process), a weld, or the like. In some implementations, one or more wire bonds and/or clips can function as an input and/or output power terminal, a signal terminal, a power terminal, or another suitable terminal.

As illustrated in the Straight-On View of apparatus 100, and as even more pronounced in the Side View, conductive element 112 may be configured to electrically couple the first gate pad 108-G of first semiconductor die 106-1 and the second gate pad 108-G of second semiconductor die 106-2 via respective resistors 110-1 and 110-2 that are mounted on gate pads 108-G. In this way, the resistors 110-1 and 110-2 are shown to be in series with conductive element 112 so that the gate terminals themselves are not directly connected to one another, but, rather, the shared gate node connects to each gate terminal via gate resistances that help with current sharing/balancing. As has been mentioned, and as will be illustrated in more detail below, the on-pad placement of these input resistors may be highly advantageous for the compact packaging of the semiconductor dies. Rather than surface mount resistors spanning dedicated and electrically-isolated portions of substrate 102 (and interconnected via patterned pads and traces on substrate 102 or additional conductive elements such as wires or clips), resistors 110-1 and 110-2 are stacked directly on the input pads where the resistance is desired, thereby taking up no additional area of substrate 102.

As shown, the ability of resistors 110-1 and 110-2 to be mounted on gate pads 108-G and to thereby provide these benefits stems in part from the form factor of the resistors themselves (i.e., the way that the resistors themselves are packaged). More particularly, FIG. 1 shows that the first resistor and the second resistor each have a leadless package design with a first terminal on a first surface (e.g., a top surface) and a second terminal on a second surface opposite the first surface (e.g., a bottom surface). In some examples, first resistor 110-1 and second resistor 110-2 may have the same resistance value. As both resistors are coupled to their respective gate pads 108-G between conductive element 112 and the gate pad 108-G, this could help each FET to have an equal gate resistance, thereby assisting with current balancing (e.g., reducing a deviation of how much current flows through each of the FETs when switching). In other examples, first resistor 110-1 and second resistor 110-2 could have different resistance values (e.g., to offset differences between the FETs implemented by semiconductor die 106-1 and 106-2 in the event that the FETs are not identical, or for other reasons).

To further illustrate the form factor or packaging of the resistors 110 that are mounted on the pads of the semiconductor dies (i.e., resistors 110-1 and 110-2), FIG. 1 shows an example resistor 110 in three-dimensional closeup (in the dotted circle expansion extending out of resistor 110-2 in both the Straight-On and Side Views). This example resistor 110 represents both resistors 110-1 and 110-2, as well as other resistors used herein for on-pad input resistance for compact packaging of semiconductor dies. In this drawing, the first surface and second surface (which is opposite the first surface) serve as terminals for the leadless component and are shaded in black, while the rest of the resistor component is white. Each surface will be understood to be conductive so that it can be physically and electrically coupled to a conductive surface (e.g., a pad 108-G of a semiconductor die such as semiconductor dies 106-1 or 106-2) and/or so that it can be physically and electrically coupled to a conductive element (e.g., a wire, a clip, etc.) such as conductive element 112.

Leadless resistor components such as these resistors 110 may be referred to by other names (e.g., bondable components, etc.) and may be distinguished from discrete components packaged using surface mount technology (SMT) by the absence of leads on the components and the way that terminals of the component, implemented by the conductive surfaces shown, may be electrically connected to other conductors. As will be made apparent with various examples described below, the leadless form factor of resistors 110 may allow for significant flexibility in how the component is physically and electrically coupled to other elements of the apparatus.

In some implementations, the resistor 110 may be reversible such that each surface can perform the same role and the orientation of the resistor is unimportant. In other implementations, different surfaces could use different materials such that the orientation may be accounted for as the resistor 110 is mounted and integrated with the circuit. For instance, one surface could have a conductive adhesive applied that is configured to adhere to the gate pads 108-G while the opposite surface could be constructed of a material configured to form a strong joint when conductive element 112 is soldered or sintered thereto. A top-side termination, for example, could be constructed from a nickel-gold alloy well-suited for direct aluminum wire bonding (or other suitable connection techniques) while a bottom-side termination could be well-suited for various mechanisms whereby the component is both physically and electrically coupled to a conductive surface below it (e.g., by way of soldering, silver sintering, conductive adhesion, etc.).

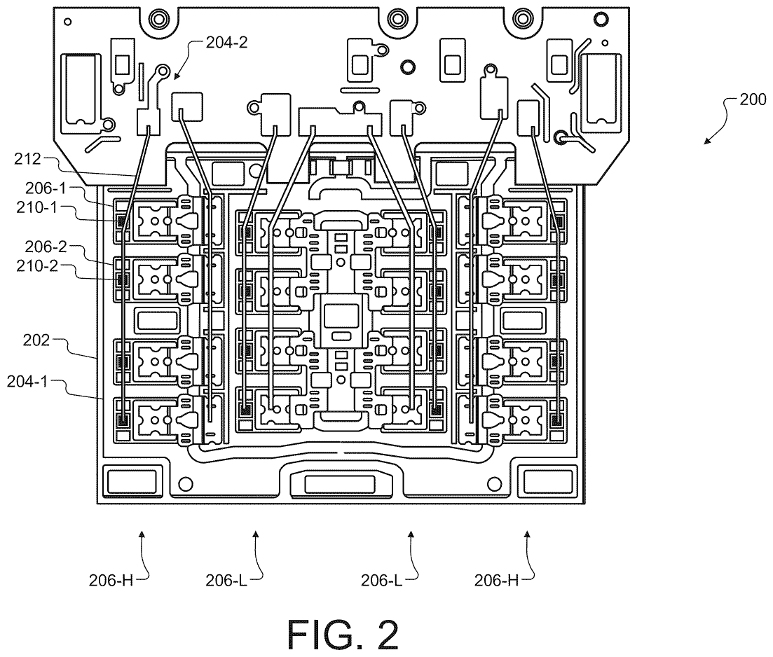

FIG. 2 shows certain aspects of an illustrative implementation of a power inverter apparatus 200 featuring on-pad input resistance for compact packaging of semiconductor dies in accordance with principles described herein. Power inverter apparatus 200 will be understood to be one example implementation of the apparatus 100 described above. More specifically, this implementation of apparatus 100 is an integrated circuit implementing a power inverter apparatus (e.g., an apparatus configured to convert DC power input to AC power output or, in other words, to convert DC current to AC current) configured for use in an automotive application. As will be described and illustrated in more detail below, an integrated circuit such as power inverter apparatus 200 may be used with other similar integrated circuits and other elements (e.g., a heat sink on which the apparatuses are installed) to build a power inverter device that is configured to be integrated with an electric vehicle or other suitable system.

As shown, certain elements of power inverter apparatus 200 (as well as like elements in other figures described below) are labeled using a similar numbering scheme as introduced in relation to FIG. 1. For example, as shown, a substrate 202 (implementing substrate 102 of FIG. 1) is shown to include multiple conductive portions including a portion 204-1 (implementing portion 104-1 of FIG. 1) and a portion 204-2 (implementing portion 104-2 of FIG. 1). Disposed on portion 204-1, power inverter apparatus 200 is shown to include a first semiconductor die 206-1 (implementing semiconductor die 106-1 of FIG. 1), a second semiconductor die 206-2 (implementing semiconductor die 106-2 of FIG. 1), and various additional semiconductor dies (not explicitly labeled). Like the semiconductor dies 106-1 and 106-2 of apparatus 100, each of the semiconductor dies of power inverter apparatus 200 (including first semiconductor die 206-1 and second semiconductor die 206-2) may implement power FETs (e.g., power MOSFETS, power JFETs, etc.). As such, each semiconductor die may include a plurality of pads (not explicitly labeled in FIG. 2) that include at least a source pad (implementing source pads 108-S of FIG. 1), a gate pad (implementing gate pads 108-G of FIG. 1), and a drain pad (on the bottom surface and not visible in either FIG. 1 or FIG. 2).

On each respective gate pad, a resistor (also referred to as a gate resistor) may be mounted to help with current sharing between the various transistor dies. More particularly, a first resistor 210-1 (implementing first resistor 110-1 of FIG. 1) is shown to be mounted on the gate pad of first semiconductor die 206-1, and a second resistor 210-2 (implementing second resistor 110-2 of FIG. 1) is shown to be mounted on the gate pad of second semiconductor die 206-2. A conductive element 212 (implementing conductive element 112 of FIG. 1) is shown to connect a shared gate node (at portion 204-2) with each of the gate pads of the FETs implemented by the semiconductor dies (including the gate pads of semiconductor dies 206-1 and 206-2). Rather than connecting directly to the gate pads of the dies, it will be understood that conductive element 212 is coupled to the gate resistors (including first resistor 210-1 and second resistor 210-2) so as to help minimize any deviation of current flowing through the various transistors as they operate in their parallel configuration.

Power inverter apparatus 200 may implement a half-bridge inverter circuit, which would generally include two transistors referred to as a high-side transistor and a low-side transistor. In a half-bridge inverter, the high-side transistor can be used to switch a positive voltage rail to a load while the low-side transistor can be used to switch a negative voltage rail (e.g., a ground rail) to the load. By controlling the switching of these transistors, the inverter can produce AC voltage of various amplitudes and frequencies as may serve a particular implementation. Half-bridge circuits may also be combined in a specific configuration to form a full-bridge circuit. This configuration would allow for more control (e.g., of a polarity and magnitude of the voltage across a load, etc.), thereby making the power inverter useful for applications such as motor control, power conversion, and so forth.

For an application or use case involving more current than a singular high-side or low-side transistor is configured to handle, multiple power transistors can be connected in parallel to collectively handle the large amounts of current. In such configurations, there would thus be one set of transistors connected in parallel to serve as the high-side transistors of the circuit, another set of transistors connected in parallel to serve as the low-side transistors of the circuit, and connections between these two sets to form the high-current half-bridge circuit. In the example of power inverter apparatus 200, eight individual semiconductor dies implementing eight FETs are connected in parallel with one another on outer columns of the apparatus (four on the left and four on the right) and labeled as high-side transistors 206-H (‘H’ for “high-side”). Eight additional semiconductor dies implementing eight additional FETs are also shown to be connected in parallel with one another (though not in parallel with high-side transistors 206-H) on inner columns of the apparatus and labeled as low-side transistors 206-L (‘L’ for “low-side”).

The FETs implemented by the first and second semiconductor dies referred to in the general example of apparatus 100 and other example implementations described herein (e.g., first semiconductor die 206-1 and second semiconductor die 206-2 in the example implementation of power inverter apparatus 200) could both refer to high-side transistors of a power inverter circuit (e.g., a half-bridge circuit, etc.) or could both refer to low-side transistors of the power inverter circuit. Because high-side and low-side transistors of a power inverter circuit would generally each have their own gate node, the first and second FETs of these examples (which are connected to a shared gate node by conductive elements such as conductive elements 112 or 212) would generally be on the same side.

In the example of power inverter apparatus 200, FIG. 2 shows that a first FET implemented by first semiconductor die 206-1 and a second FET implemented by second semiconductor die 206-2 are configured as high-side transistors 206-H in the power inverter circuit. These high-side transistors 206-H are electrically connected in parallel to allow the power inverter circuit to process more current than either of the high-side transistors 206-H could process operating alone. While not explicitly labeled in FIG. 2, it will be understood that a first FET and a second FET implemented by semiconductor dies in the inner columns of the apparatus could also be connected in the same way. For example, this first and second FET would both be configured as low-side transistors 206-L in the power inverter circuit, where, again, the low-side transistors 206-L are electrically connected in parallel to allow the power inverter circuit to process more current than either of the low-side transistors 206-L could process operating alone.

In some implementations including the implementation of power inverter apparatus 200 (though many elements are not explicitly labeled due to space constraints), it will be understood that on-pad input resistance principles may be applied to transistors on both the high side and the low side. For example, in an example where a first FET (e.g., implemented by first semiconductor die 206-1) and a second FET (e.g., implemented by second semiconductor die 206-2) are configured as high-side transistors electrically connected in parallel in the power inverter circuit, the apparatus (e.g., power inverter apparatus 200) may further include: 1) a third semiconductor die disposed on the substrate and implementing a third FET configured as a first low-side transistor (e.g., one of low-side transistors 206-L) in the power inverter circuit, and 2) a fourth semiconductor die disposed on the substrate and implementing a fourth FET configured as a second low-side transistor (e.g., another one of low-side transistors 206-L) electrically connected in parallel with the first low-side transistor in the power inverter circuit.

While this general example mentions four FETs implemented by four semiconductor dies (i.e., two FETs each on the high side and the low side of the power inverter circuit), it will be understood that more than two FETs on each side may also be used. As shown in the example of power inverter apparatus 200, for example, an apparatus implementing a power inverter circuit may include: 1) at least eight high-side FETs electrically connected in parallel (and including the first FET and the second FET mentioned above); and 2) at least eight low-side FETs electrically connected in parallel (and including the third FET and the fourth FET mentioned above).

While only two resistors 210-1 and 210-2 are explicitly labeled for power inverter apparatus 200, FIG. 2 shows that black resistors are mounted on gate pads of all eight high-side transistors 206-H in this example (including the first semiconductor die 206-1 and the second semiconductor die 206-2), as well as on gate pads of all eight low-side transistors 206-L in the example. Different conductive elements similar to the explicitly labeled conductive element 212 are shown to connect the columns of resistors in a similar way as has been described. It will be understood that these conductive elements may be connected to two shared gate nodes, one for the high side and one for the low side. In other words, the conductive element 212 may be electrically coupled with the conductive element connecting the gate resistors of the high-side transistors 206-H on the right-hand side of power inverter apparatus 200 (the connection not being explicitly shown), while the two conductive elements connecting gate resistors on the inner columns of low-side transistors 206-L may similarly be electrically coupled to one another at a shared node (again, the connection not being explicitly shown).

As has been described, these gate resistors may help balance the amount of current flowing through each of the high-side transistors 206-H and the low-side transistors 206-L so that there is little deviation between how much current each helps to switch. The resistance values may be relatively low (e.g., 5 ohms, 10 ohms, etc.) and may be equal for each resistor (or at least for each resistor on the high side and for each resistor on the low side). The resistors may serve to decouple the gates of the FETs to prevent oscillations and help ensure that each FET is switched on with a similar voltage and speed to draw a similar amount of current.

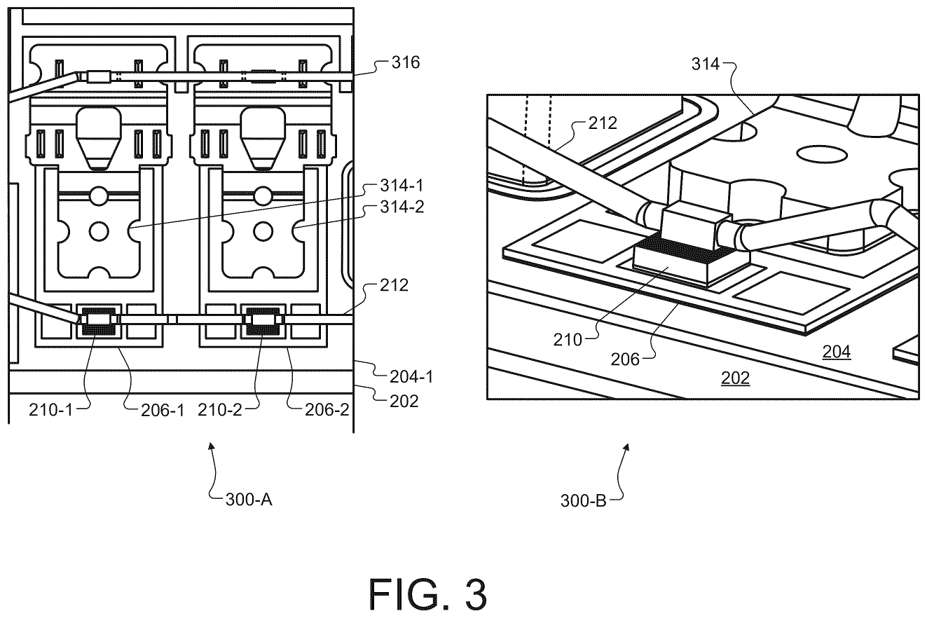

FIG. 3 shows additional views of certain aspects of the power inverter apparatus 200 described above in relation to FIG. 2. First, FIG. 3 shows a closeup view 300-A of certain elements disposed within power inverter apparatus 200 (e.g., elements from the left-side column of high-side transistors 206-H described and labeled in FIG. 2). As shown in closeup view 300-A, substrate 202 includes conductive portion 204-1 on which various semiconductor dies, including first semiconductor die 206-1 and second semiconductor die 206-2, are disposed. As these semiconductor dies implement FETs such as power MOSFETs, they may include the same set of pads as has been described. On the gate pads in the middle, closeup view 300-A shows respective resistors 210-1 (on the gate pad of first semiconductor die 206-1) and 210-2 (on the gate pad of second semiconductor die 206-2). The conductive element 212 is also shown to be coupled with these resistors 210 (and, indirectly, to the gate pads to which the resistors are mounted) and to extend in both directions so as to couple all of the gate pads (with corresponding input resistors) to the shared gate node for the high-side transistors of the power inverter apparatus.

A few other elements that are depicted but were not called out specifically in FIG. 2 are also illustrated and labeled in FIG. 3. For example, a clip 314-1 coupled to the source pad of first semiconductor die 206-1 and a corresponding clip 314-2 coupled to the source pad of second semiconductor die 206-2 are shown, along with a conductive element 316 that connects these clips 314-1 and 314-2 (as well as other clips on other FETs not shown in view 300-A) together and to a shared source node for the high-side transistors.

FIG. 3 further shows a perspective view 300-B of one of the resistors 210 (e.g., either of resistors 210-1 or 210-2, or another one of the resistors included within power inverter apparatus 200) as the resistor is coupled to a gate pad of a semiconductor die 206 (e.g., either of semiconductor dies 206-1 or 206-2, or another one of the semiconductor dies included within power inverter apparatus 200) between the conductive element 212 and the gate pad. Substrate 202 and the portion 204 hosting the semiconductor die 206 are also labeled in perspective view 300-B, as is the conductive element 212 and a clip 314 coupled to the die's source pad (e.g., either of clips 314-1 or 314-2, or another one of the clips included within power inverter apparatus 200).

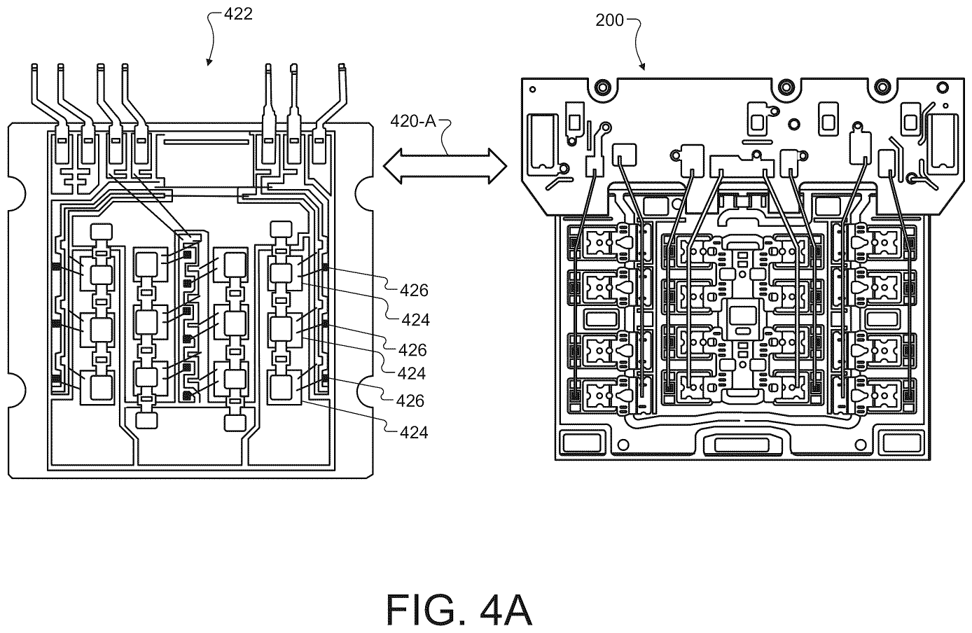

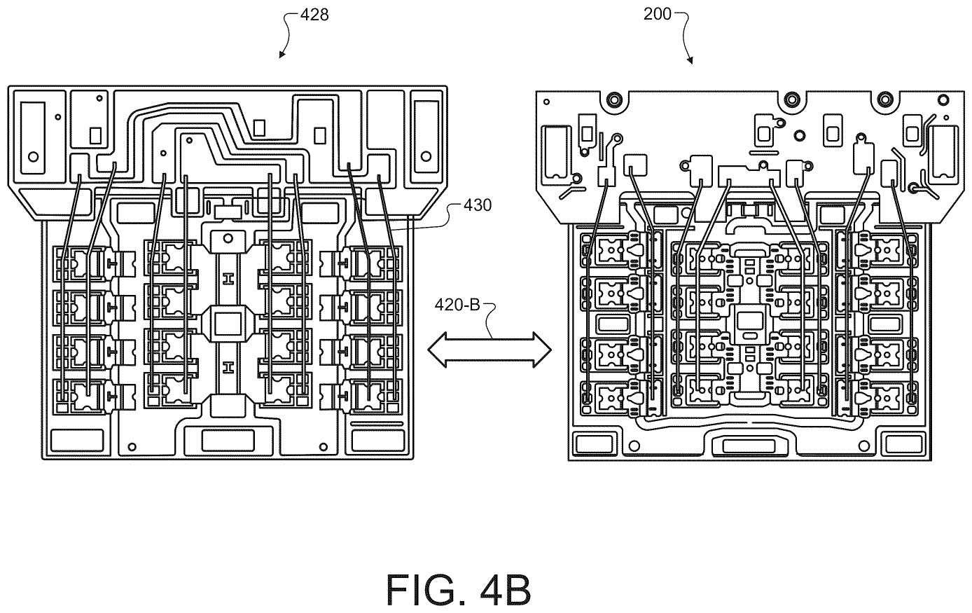

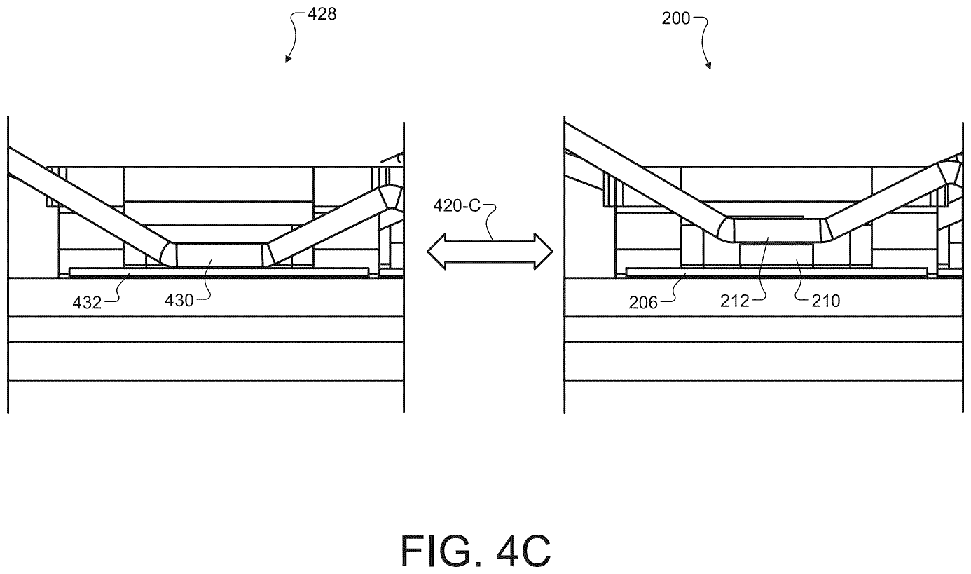

FIGS. 4A-4C show contrasts between power inverter apparatus 200 (as it was described and illustrated above in relation to FIGS. 2-3) and alternative power inverter apparatuses (e.g., conventional apparatuses, etc.) that, unlike power inverter apparatus 200, do not implement on-pad input resistance principles described herein for compact packaging of semiconductor dies.

In FIG. 4A, a contrast 420-A is shown between: 1) a conventional power inverter apparatus 422, which is not an implementation of apparatus 100 and does not utilize on-pad input resistance for compact packaging, and 2) power inverter apparatus 200, which is an implementation of apparatus 100 that utilizes on-pad input resistance for compact packaging as described herein.

As with power inverter apparatus 200, power inverter apparatus 422 includes a number of transistors (e.g., power FETs, etc.) that are connected in parallel to form a half-bridge circuit. A few of these transistors are labeled as transistors 424 and will be understood to include similar pads as the transistors implemented by semiconductor dies 206 described above (though the pads are not explicitly outlined or labeled in FIG. 4A). The gates of each of these transistors are given input resistors for the same reasons described above for power inverter apparatus 200 (e.g., to assist with current balancing between the transistors, etc.). These resistors are also drawn as black squares and a few of them are labeled as resistors 426. However, whereas the input resistors 210 in power inverter apparatus 200 are mounted right on the gate pads of the transistors so as to support compact packaging (by not taking up extra space on the substrate), the input resistors 426 of conventional power inverter apparatus 422 are shown to be placed next to the respective transistors 424 on their own dedicated and isolated portions of the substrate, and to connect the transistor pads via wires.

This type of placement is shown to take more space of the substrate, since each resistor 426 is mounted on a small portion of the substrate that is isolated from the portions on which the transistors are mounted. Potentially as a result of this placement, the substrate may be larger than it would otherwise be (therefore also increasing the cost of the substrate) and/or may include less space for electronic components (e.g., holding only 12 transistors, in this example, rather than the 16 transistors supported by power inverter apparatus 200). Moreover, there may be more complexity, more room for error, less efficiency, and so forth, due to each gate pad being connected, via separate wire bonds, to the gate resistors 426. The increased compactness of the packaging for power inverter apparatus 200, as well as the corresponding increase in efficiency and current capacity (due to having more transistors) and decrease in cost and complexity (due to having a smaller substrate and fewer wires to connect, etc.) may all have significant technical effects and provide significant benefits, as have been described.

In FIG. 4B, a contrast 420-B is shown between: 1) another conventional power inverter apparatus 428 that, again, will be understood to not implement apparatus 100 and to not utilize on-pad input resistance for compact packaging as described herein, and 2) the same power inverter apparatus 200 that has been described (i.e., the implementation of apparatus 100 that utilizes on-pad input resistance for compact packaging).

Whereas conventional power inverter apparatus 422 included input resistors for each of the transistors of the apparatus (though transistors were not mounted on the gate pads as in power inverter apparatus 200), conventional power inverter apparatus 428 shows a similar apparatus as power inverter apparatus 200 except without any gate resistors employed in the design. Rather, as shown, various conductive elements including a conductive element 430 on the right side of the apparatus, will be understood to connect the gate pads in a similar way as has been described for power inverter apparatus 200. The difference, however, is that, without the input resistance provided by resistors such as resistors 210, there may be much more current flow discrepancy between the various transistors in the circuit, creating certain problems or at least omitting some of the on-pad input resistance benefits that have been described.

It is noted that the top section of conventional power inverter apparatus 428 illustrates additional detail regarding how shared nodes may be interconnected. For instance, a first irregularly-shaped portion of the substrate is shown to connect the tip of the left-most conductive element and the right-most conductive element (i.e., the conductive element 430) in a single high-side shared gate node. Similarly, a second irregularly-shaped portion of the substrate is shown to connect conductive elements from the inner columns to form a low-side shared gate node. Other portions similarly connect conductive elements from corresponding clips attached to the source gates to further connect these terminals of the high-side and low-side transistors in parallel. While these details are not depicted for power inverter apparatus 200 (e.g., due to a mask that may cover the detail in these illustrations), it will be understood that power inverter apparatus 200 may include the same or similar connections to form shared nodes in a similar manner.

FIG. 4C shows additional contrasting aspects between a conventional power inverter apparatus such as power inverter apparatus 428 and an implementation of apparatus 100 such as power inverter apparatus 200. Specifically, FIG. 4C depicts a contrast 420-C between: 1) a closeup side view of part of power inverter apparatus 428 showing a connection between conductive element 430 and a gate pad of a semiconductor die 432, and 2) a closeup side view of a corresponding part of power inverter apparatus 200 showing a connection between conductive element 212 and a gate pad of a semiconductor die 206. As shown, one difference between these connections is that, in the example of power inverter apparatus 200, a resistor 210 coupled to the gate pad is connected between conductive element 212 and the gate pad of the semiconductor die 206. Such a resistor is not present in the connection of conductive element 430 to semiconductor die 432 in power inverter apparatus 428.

With conductive elements and patterned conductive portions of the substrate providing the desired electrical couplings between transistors and other elements of an apparatus (e.g., power inverter apparatus 200), the package of the apparatus may include a plurality of leads interconnected with the circuitry to assist the circuit with connecting to external components (e.g., to connect the apparatus to a printed circuit board or the like). To this end, an apparatus such as apparatus 100 or power inverter apparatus 200 may further include a leadframe including a plurality of leads, as well as a molding compound that at least partially encapsulates the substrate, the semiconductor dies, the conductive elements, the resistor, and the plurality of leads.

As used herein, a leadframe may refer to conductive portions of a device package (e.g., conductive leads, terminals, etc.) that are configured to provide external connection points for the package. For example, wire bonds, clips, or other electrical connections may be used to couple individual leads of the leadframe to circuitry within the device package (e.g., a substrate, a semiconductor die, etc.) and these leads may extend from the device package (e.g., emerging from the molding material) to connect to external circuitry in any suitable way, such as by being soldered or otherwise coupled to a circuit board. Accordingly, the leadframe can be referred to as a conductive portion or a metal portion of the device package. In some implementations, one or more portions of a leadframe can be coupled to a pad (e.g., a bond pad) on at least a portion of a DBM substrate.

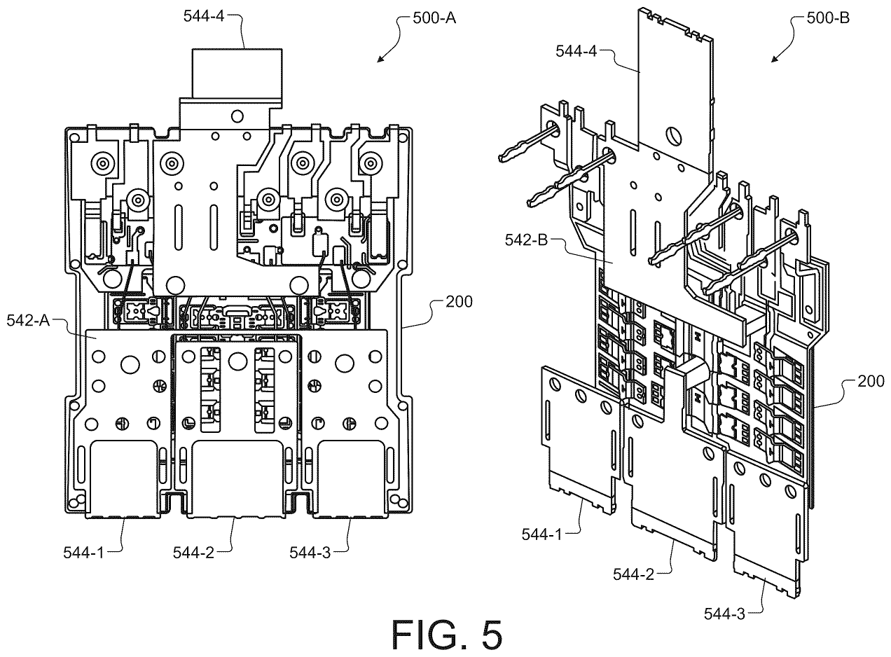

To illustrate, FIG. 5 shows views of power inverter apparatus 200 integrated with possible leadframes in accordance with principles described herein. First, a straight-on view 500-A shows a leadframe 542-A that connects to the substrate of power inverter apparatus 200 and provides connections to various leads 544-1, 544-2, 544-3, and 544-4 (shown to be truncated or without extensions yet installed in the depiction of FIG. 5). A perspective view 500-B then shows another leadframe 542-B that similarly connects to the substrate and provides connections to leads 544-1 to 544-4 with a similar layout.

While the precise connections between these leadframes (i.e., leadframes 542-A and 542-B) and the shared nodes of power inverter apparatus 200 (e.g., a high-side shared gate node, a low-side shared gate node, etc.) are not explicitly shown in FIG. 5, it will be understood that the leadframes may connect to these nodes in a manner that provides a desired lead arrangement (e.g., pinout) for the apparatus when the package is complete. For example, this lead arrangement may receive a positive DC input (DC+) on leads 544-1 and 544-3, a negative DC input (DC-or ground) on lead 544-2, and may provide an AC output (AC) on lead 544-4. Extended pins configured to interconnect with certain platforms (e.g., PCBs, heatsinks, active cooling apparatuses, other electronic or mechanical components, etc.) may also be included, as prominently illustrated in perspective view 500-B. These leads and pins may ultimately extend from the device package (e.g., emerging from the molding material after it is put in place) to connect to external circuitry in any suitable way, such as by being soldered or otherwise coupled to a circuit board or heatsink.

Although referred to, by way of example, as a leadframe in at least some portions of this detailed description, leadframes described herein may include any type of conductive portion of a package (e.g., conductive portion, conductive terminal, etc.) that can provide an external connection point from a package. Accordingly, the leadframe can be referred to as a conductive portion of the package. In some implementations, one or more portions of a leadframe can be coupled to a pad (e.g., a bond pad) on at least a portion of a DBM substrate.

Semiconductor device packages described herein may include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

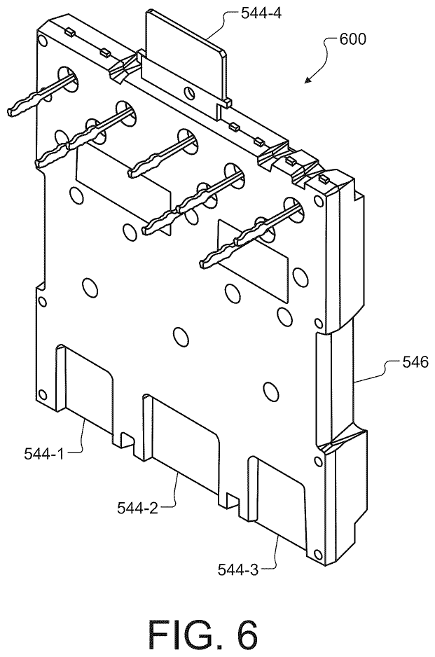

FIG. 6 shows certain aspects of a packaged power inverter apparatus 600 encapsulated in a molding compound 546 in accordance with principles described herein. It will be understood that packaged power inverter apparatus 600 may include the various elements of power inverter apparatus 200 that have been described (e.g., the substrate with the semiconductor dies, conductive elements, resistors, etc.), as well as the leadframe (e.g., leadframe 542-A or leadframe 542-B) and possibly other elements that have not been explicitly shown or described. Additionally, molding compound 546 is shown to have been added to provide protection and structural support to all of these elements that it encapsulates. Each of the leads 544-1 to 544-4, as well as various pins mentioned above, are shown to be accessible even after molding compound 546 has been applied, thereby allowing the power inverter circuitry encapsulated in the molding compound 546 for convenient external connections (e.g., to external circuitry, heatsinks, etc.).

In some implementations, a molding compound (e.g., molding material or compound, an encapsulation material) can be or can include a non-conducting layer/material. In some implementations, the molding compound is a non-conducting material which can be formed (applied, etc.) using a transfer molding process or a compression molding process. For example, the molding material may be or include an organic material (e.g., a polymer or plastic material such as epoxy, silicone, phenolic resin, etc.), an inorganic material (e.g., a non-conductive ceramic or conductive metal material, etc.), and/or other suitable materials as may serve a particular implementation. In some implementations, the molding compound can include a separate plastic housing that is included in the semiconductor device assembly.

In some implementations, a spacer material may be included between certain elements of the apparatus such as between a leadframe and a substrate, between a semiconductor die and a substrate, between the apparatus and a substrate, or the like. For example, such spacer material can be or can include an epoxy, a silicone adhesive, a conductive material, a non-conductive material, an organic material, a semiconductor material, a metal alloy, a metal foam, a phase change material, or the like.

In some implementations, a module (e.g., an apparatus including a semiconductor device within a package, such as apparatus 100 or power inverter apparatus 200) can be included in another module. The module can be referred to as a package. For example, one or more modules can be one or more sub-modules included within another module. In other words, a first module can be included as a sub-module within a second module. Referring more particularly to modules such as are implemented by apparatus 100, these may serve as sub-modules to a larger module such as a circuit, system, or device that employs apparatus 100 and may include a plurality of instances of apparatus 100.

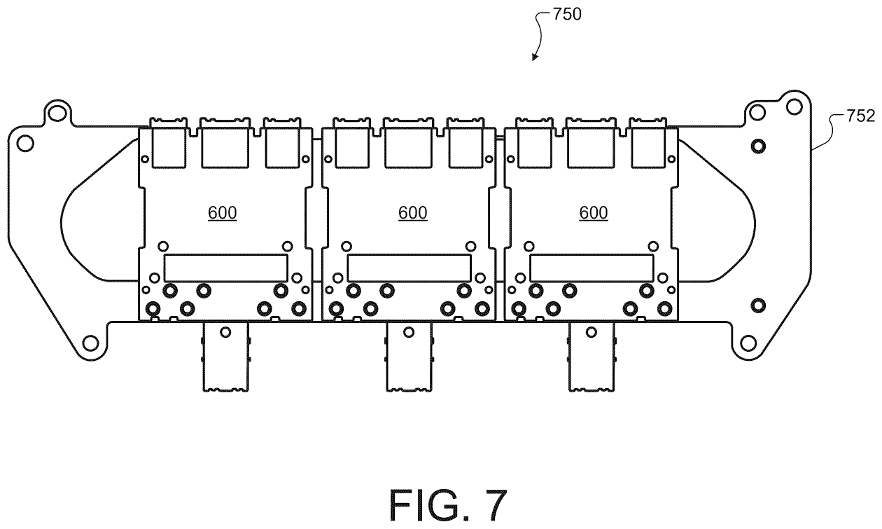

To illustrate an example of a module that can use power inverter apparatus 200 (and the fully packaged power inverter apparatus 600, more particularly) as a sub-module, FIG. 7 shows certain aspects of an illustrative power inverter device 750. Illustrative power inverter device 750 is shown to feature a plurality of power inverter apparatuses (i.e., instances of packaged power inverter apparatus 600) installed on a heatsink 752 in accordance with principles described herein. More particularly, power inverter device 750 may include a heatsink 752 and a plurality of power inverter apparatuses 600 installed on the heatsink 752. The plurality of power inverter apparatuses may each represent integrated circuits implementing power inverter apparatuses configured for use in an automotive application, such as have been described. Each of these power inverter apparatuses may include elements such as those that have been described for power inverter apparatus 200. For example, one of the power inverter apparatuses 600 may include at least: 1) a substrate, 2) a first semiconductor die disposed on the substrate and implementing a first FET with a gate terminal accessible by a first gate pad, 3) a second semiconductor die disposed on the substrate and implementing a second FET with a gate terminal accessible by a second gate pad, 4) a conductive element configured to electrically couple the first gate pad and the second gate pad to a shared gate node, 5) a first resistor coupled to the first gate pad between the conductive element and the first gate pad, and 6) a second resistor coupled to the second gate pad between the conductive element and the second gate pad, among other elements as may serve a particular implementation.

As has been described in other examples, the first FET and the second FET in this implementation may be configured as high-side transistors electrically connected in parallel in a power inverter circuit implemented by the power inverter apparatus. As such, the power inverter device may further comprise: 1) a third semiconductor die disposed on the substrate and implementing a third FET configured as a first low-side transistor in the power inverter circuit, and 2) a fourth semiconductor die disposed on the substrate and implementing a fourth FET configured as a second low-side transistor electrically connected in parallel with the first low-side transistor in the power inverter circuit. As described in other examples above, the substrate of each packaged power inverter apparatus 600 may be implemented by a DBM substrate (e.g., a DBC substrate, etc.) having a patterned layer of metal bonded to a ceramic substrate, while the first and second semiconductor dies of the apparatuses may be SiC dies fabricated using a SiC semiconductor and the first and second FETs may be power MOSFETs. In other implementations, other suitable components (e.g., Si dies, JFETs, etc.) may additionally or alternatively be employed.

Heatsink 752 may be implemented as any suitable system configured to draw heat away from the packaged power inverter apparatuses 600 to keep the apparatuses within suitable temperature parameters even as they process large amounts of current that would tend to heat them up. In certain implementations, heatsink 752 may include or be implemented by an active cooling system configured to use fluid to transfer heat away from the plurality of power inverter apparatuses. For example, fluid may be pumped through the cooling system (i.e., through heatsink 752) so that the fluid can draw heat away from the packaged power inverter apparatuses 600 and carry the heat elsewhere to prevent these components from overheating.

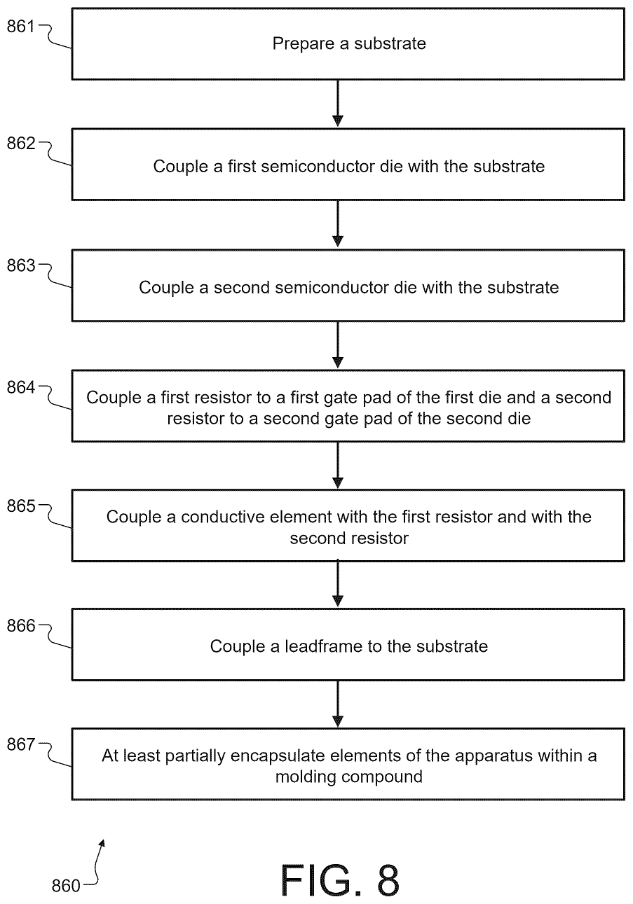

FIG. 8 shows an illustrative method 860 for constructing an apparatus featuring on-pad input resistance for compact packaging of semiconductor dies in accordance with principles described herein. For example, an apparatus such as packaged power inverter apparatus 600 or any of the other example apparatus implementations described herein may be assembled or constructed based on the steps of method 860. While FIG. 8 shows illustrative operations 861-867 according to one implementation, other implementations of method 860 may omit, add to, reorder, and/or modify any of the operations 861-867 shown in FIG. 8. In some examples, multiple operations shown in FIG. 8 or described in relation to FIG. 8 may be performed concurrently (e.g., in parallel) with one another, rather than being performed sequentially as illustrated and/or described. Each of operations 861-867 will now be described in more detail.

At operation 861, a substrate may be prepared for use in a semiconductor package. For example, any suitable techniques for substrate preparation may be performed to create a substrate such as any of the substrates described herein. In the example of a DBM substrate, for example, operation 861 may involve preparing the ceramic substrate, preparing a conductive foil (e.g., a copper foil, etc.), direct bonding the foil to the ceramic substrate (e.g., using a high-temperature brazing process or the like), etching the desired pattern into the metal on one side of the substrate to generate various conductive portions that are electrically isolated from one another, and other suitable tasks such as may be appropriate for a particular application (e.g., drilling vias, applying a solder mask, performing surface finishing, etc.). In certain examples, preparing a substrate at operation may involve procuring a pre-fabricated substrate from a supplier source, rather than constructing or building it in the ways described above.

At operation 862, a first semiconductor die may be coupled with the substrate prepared for this purpose at operation 861. The first semiconductor die may implement a first FET (e.g., a power MOSFET, etc.) with a gate terminal accessible by a first gate pad, as well as other terminals (e.g., a source terminal, a drain terminal, etc.) accessible by other pads as have been described herein. The coupling of the first semiconductor die at operation 862 may involve soldering the semiconductor die to a particular portion of the substrate, sintering the semiconductor die to the particular portion of the substrate, or otherwise physically and/or electrically coupling the semiconductor die to that portion of the substrate.

At operation 863, a second semiconductor die may be coupled with the substrate prepared at operation 861. Like the first semiconductor die, the second semiconductor die may implement a second FET (e.g., another power MOSFET) with various terminals accessible by various pads, including a gate terminal accessible by a second gate pad. The coupling of the second semiconductor die at operation 863 may involve soldering, sintering, or otherwise physically and/or electrically coupling the semiconductor die to a portion of the substrate. In some implementations, the second semiconductor die may be fabricated using the same type of semiconductor as the first semiconductor die (e.g., silicon (Si), silicon carbide (SiC), etc.). In other implementations, the two semiconductor dies may be fabricated using different types of semiconductor materials (a hybrid die scenario described above).

At operation 864, resistors may be coupled to the gate pads of the semiconductor dies applied at operations 862 and 863. More particularly, a first resistor with a leadless package design and a first terminal on a first surface and a second terminal on a second surface opposite the first surface (also referred to as a bondable package) may be coupled to the first gate pad of the first semiconductor die that was coupled to the substrate at operation 862. A second resistor with the same type of leadless package design may be coupled to the second gate pad of the second semiconductor die that was coupled to the substrate at operation 863.

At operation 865, a conductive element may be coupled with the first resistor on the first gate pad and with the second resistor on the second gate pad. For example, a gate wire may be soldered or sintered so as to connect various gate pads for various transistors (e.g., gate pads for some or all of a plurality of high-side transistors, gate pads for some or all of a plurality of low-side transistors, etc.) including the first and second FETs. The conductive element may connect to each gate pad by way of the resistor coupled (i.e., mounted) to the gate pad so that the resistor provides an on-pad input resistance for the FET that helps provide compact packaging of the semiconductor dies in accordance with principles described herein.

At operation 866, a leadframe may be coupled to the substrate, the leadframe including a plurality of leads that can be connected to elements of the apparatus (e.g., a shared gate node associated with the conductive element coupled at operation 865, etc.) to allow external connections to these elements of the apparatus.

At operation 867, a molding compound may then be used to at least partially encapsulate the substrate, the first semiconductor die, the second semiconductor die, the conductive element, the first resistor, the second resistor, and the leadframe with the plurality of leads.

The following examples describe implementations (e.g., apparatuses, methods, devices, etc.) of on-pad input resistance for compact packaging of semiconductor dies in accordance with principles described herein.
Example 1: An apparatus comprising: a substrate; a first semiconductor die disposed on the substrate and implementing a first field-effect transistor with a gate terminal accessible by a first gate pad; a second semiconductor die disposed on the substrate and implementing a second field-effect transistor with a gate terminal accessible by a second gate pad; a conductive element configured to electrically couple the first gate pad and the second gate pad to a shared gate node; a first resistor coupled to the first gate pad between the conductive element and the first gate pad; and a second resistor coupled to the second gate pad between the conductive element and the second gate pad.
Example 2: The apparatus of any of the preceding examples, wherein the first resistor and the second resistor each have a leadless package design with a first terminal on a first surface and a second terminal on a second surface opposite the first surface.
Example 3: The apparatus of any of the preceding examples, wherein the first field-effect transistor and the second field-effect transistor are configured as high-side transistors in a power inverter circuit, the high-side transistors electrically connected in parallel to allow the power inverter circuit to process more current than either of the high-side transistors could process operating alone.
Example 4: The apparatus of any of the preceding examples, wherein the first field-effect transistor and the second field-effect transistor are configured as low-side transistors in a power inverter circuit, the low-side transistors electrically connected in parallel to allow the power inverter circuit to process more current than either of the low-side transistors could process operating alone.
Example 5: The apparatus of any of the preceding examples, wherein: the first field-effect transistor and the second field-effect transistor are configured as high-side transistors electrically connected in parallel in a power inverter circuit; and the apparatus further comprises: a third semiconductor die disposed on the substrate and implementing a third field-effect transistor configured as a first low-side transistor in the power inverter circuit, and a fourth semiconductor die disposed on the substrate and implementing a fourth field-effect transistor configured as a second low-side transistor electrically connected in parallel with the first low-side transistor in the power inverter circuit.
Example 6: The apparatus of any of the preceding examples, wherein the apparatus implements the power inverter circuit, the power inverter circuit comprising: at least eight high-side field-effect transistors electrically connected in parallel and including the first field-effect transistor and the second field-effect transistor; and at least eight low-side field-effect transistors electrically connected in parallel and including the third field-effect transistor and the fourth field-effect transistor.
Example 7: The apparatus of any of the preceding examples, wherein the substrate is implemented by a direct-bonded metal (DBM) substrate having a patterned layer of metal bonded to a ceramic substrate.
Example 8: The apparatus of any of the preceding examples, wherein the first semiconductor die and the second semiconductor die are silicon carbide (SiC) dies fabricated using a SiC semiconductor.
Example 9: The apparatus of any of the preceding examples, wherein the first semiconductor die and the second semiconductor die are hybrid dies fabricated using different semiconductors, the first semiconductor die being a silicon (Si) die fabricated using a Si semiconductor and the second semiconductor die being a silicon carbide (SiC) die fabricated using a SiC semiconductor.
Example 10: The apparatus of any of the preceding examples, wherein the first field-effect transistor and the second field-effect transistor are power metal-oxide-semiconductor field-effect transistors (MOSFETs).
Example 11: The apparatus of any of the preceding examples, wherein the first resistor and the second resistor have a same resistance value.
Example 12: The apparatus of any of the preceding examples, further comprising: a leadframe including a plurality of leads; and a molding compound at least partially encapsulating the substrate, the first semiconductor die, the second semiconductor die, the conductive element, the first resistor, the second resistor, and the plurality of leads.
Example 13: The apparatus of any of the preceding examples, wherein the apparatus is an integrated circuit implementing a power inverter apparatus configured for use in an automotive application.
Example 14: A power inverter device comprising: a heatsink; and a plurality of power inverter apparatuses installed on the heatsink, the plurality of power inverter apparatuses including a power inverter apparatus comprising: a substrate, a first semiconductor die disposed on the substrate and implementing a first field-effect transistor with a gate terminal accessible by a first gate pad, a second semiconductor die disposed on the substrate and implementing a second field-effect transistor with a gate terminal accessible by a second gate pad, a conductive element configured to electrically couple the first gate pad and the second gate pad to a shared gate node, a first resistor coupled to the first gate pad between the conductive element and the first gate pad, and a second resistor coupled to the second gate pad between the conductive element and the second gate pad.
Example 15: The power inverter device of any of the preceding examples, wherein: the first field-effect transistor and the second field-effect transistor are configured as high-side transistors electrically connected in parallel in a power inverter circuit implemented by the power inverter apparatus; and the power inverter device further comprises: a third semiconductor die disposed on the substrate and implementing a third field-effect transistor configured as a first low-side transistor in the power inverter circuit, and a fourth semiconductor die disposed on the substrate and implementing a fourth field-effect transistor configured as a second low-side transistor electrically connected in parallel with the first low-side transistor in the power inverter circuit.
Example 16: The power inverter device of any of the preceding examples, wherein: the substrate is implemented by a direct-bonded metal (DBM) substrate having a patterned layer of metal bonded to a ceramic substrate; the first semiconductor die and the second semiconductor die are silicon carbide (SiC) dies fabricated using a SiC semiconductor; and the first field-effect transistor and the second field-effect transistor are power metal-oxide-semiconductor field-effect transistors (MOSFETs).
Example 17: The power inverter device of any of the preceding examples, wherein the heatsink includes an active cooling system configured to use fluid to transfer heat away from the plurality of power inverter apparatuses.
Example 18: A method comprising: preparing a substrate; coupling a first semiconductor die with the substrate, the first semiconductor die implementing a first field-effect transistor with a gate terminal accessible by a first gate pad; coupling a second semiconductor die with the substrate, the second semiconductor die implementing a second field-effect transistor with a gate terminal accessible by a second gate pad; coupling a first resistor to the first gate pad and a second resistor to the second gate pad; and coupling a conductive element with the first resistor on the first gate pad and with the second resistor on the second gate pad.
Example 19: The method of any of the preceding examples, further comprising: coupling a leadframe to the substrate, the leadframe including a plurality of leads; and at least partially encapsulating, within a molding compound, the substrate, the first semiconductor die, the second semiconductor die, the conductive element, the first resistor, the second resistor, and the plurality of leads.
Example 20: The method of any of the preceding examples, wherein: the substrate is implemented by a direct-bonded metal (DBM) substrate having a patterned layer of metal bonded to a ceramic substrate; the first semiconductor die and the second semiconductor die are silicon carbide (SiC) dies fabricated using a SiC semiconductor; and the first field-effect transistor and the second field-effect transistor are power metal-oxide-semiconductor field-effect transistors (MOSFETs).

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An apparatus comprising:
a substrate;
a first semiconductor die disposed on the substrate and implementing a first field-effect transistor with a gate terminal accessible by a first gate pad;
a second semiconductor die disposed on the substrate and implementing a second field-effect transistor with a gate terminal accessible by a second gate pad;
a conductive element configured to electrically couple the first gate pad and the second gate pad to a shared gate node;
a first resistor coupled to the first gate pad between the conductive element and the first gate pad; and
a second resistor coupled to the second gate pad between the conductive element and the second gate pad.

2. The apparatus of claim 1, wherein the first resistor and the second resistor each have a leadless package design with a first terminal on a first surface and a second terminal on a second surface opposite the first surface.

3. The apparatus of claim 1, wherein the first field-effect transistor and the second field-effect transistor are configured as high-side transistors in a power inverter circuit, the high-side transistors electrically connected in parallel to allow the power inverter circuit to process more current than either of the high-side transistors could process operating alone.

4. The apparatus of claim 1, wherein the first field-effect transistor and the second field-effect transistor are configured as low-side transistors in a power inverter circuit, the low-side transistors electrically connected in parallel to allow the power inverter circuit to process more current than either of the low-side transistors could process operating alone.

5. The apparatus of claim 1, wherein:
the first field-effect transistor and the second field-effect transistor are configured as high-side transistors electrically connected in parallel in a power inverter circuit; and
the apparatus further comprises:
a third semiconductor die disposed on the substrate and implementing a third field-effect transistor configured as a first low-side transistor in the power inverter circuit, and
a fourth semiconductor die disposed on the substrate and implementing a fourth field-effect transistor configured as a second low-side transistor electrically connected in parallel with the first low-side transistor in the power inverter circuit.

6. The apparatus of claim 5, wherein the apparatus implements the power inverter circuit, the power inverter circuit comprising:
at least eight high-side field-effect transistors electrically connected in parallel and including the first field-effect transistor and the second field-effect transistor; and
at least eight low-side field-effect transistors electrically connected in parallel and including the third field-effect transistor and the fourth field-effect transistor.

7. The apparatus of claim 1, wherein the substrate is implemented by a direct-bonded metal (DBM) substrate having a patterned layer of metal bonded to a ceramic substrate.

8. The apparatus of claim 1, wherein the first semiconductor die and the second semiconductor die are silicon carbide (SiC) dies fabricated using a SiC semiconductor.

9. The apparatus of claim 1, wherein the first semiconductor die and the second semiconductor die are hybrid dies fabricated using different semiconductors, the first semiconductor die being a silicon (Si) die fabricated using a Si semiconductor and the second semiconductor die being a silicon carbide (SiC) die fabricated using a SiC semiconductor.

10. The apparatus of claim 1, wherein the first field-effect transistor and the second field-effect transistor are power metal-oxide-semiconductor field-effect transistors (MOSFETs).

11. The apparatus of claim 1, wherein the first resistor and the second resistor have a same resistance value.

12. The apparatus of claim 1, further comprising:
a leadframe including a plurality of leads; and
a molding compound at least partially encapsulating the substrate, the first semiconductor die, the second semiconductor die, the conductive element, the first resistor, the second resistor, and the plurality of leads.

13. The apparatus of claim 1, wherein the apparatus is an integrated circuit implementing a power inverter apparatus configured for use in an automotive application.

14. A power inverter device comprising:
a heatsink; and
a plurality of power inverter apparatuses installed on the heatsink, the plurality of power inverter apparatuses including a power inverter apparatus comprising:
a substrate,
a first semiconductor die disposed on the substrate and implementing a first field-effect transistor with a gate terminal accessible by a first gate pad,
a second semiconductor die disposed on the substrate and implementing a second field-effect transistor with a gate terminal accessible by a second gate pad,
a conductive element configured to electrically couple the first gate pad and the second gate pad to a shared gate node,
a first resistor coupled to the first gate pad between the conductive element and the first gate pad, and
a second resistor coupled to the second gate pad between the conductive element and the second gate pad.

15. The power inverter device of claim 14, wherein:
the first field-effect transistor and the second field-effect transistor are configured as high-side transistors electrically connected in parallel in a power inverter circuit implemented by the power inverter apparatus; and
the power inverter device further comprises:
a third semiconductor die disposed on the substrate and implementing a third field-effect transistor configured as a first low-side transistor in the power inverter circuit, and
a fourth semiconductor die disposed on the substrate and implementing a fourth field-effect transistor configured as a second low-side transistor electrically connected in parallel with the first low-side transistor in the power inverter circuit.

16. The power inverter device of claim 14, wherein:
the substrate is implemented by a direct-bonded metal (DBM) substrate having a patterned layer of metal bonded to a ceramic substrate;
the first semiconductor die and the second semiconductor die are silicon carbide (SiC) dies fabricated using a SiC semiconductor; and
the first field-effect transistor and the second field-effect transistor are power metal-oxide-semiconductor field-effect transistors (MOSFETs).

17. The power inverter device of claim 14, wherein the heatsink includes an active cooling system configured to use fluid to transfer heat away from the plurality of power inverter apparatuses.

18. A method comprising:
preparing a substrate;
coupling a first semiconductor die with the substrate, the first semiconductor die implementing a first field-effect transistor with a gate terminal accessible by a first gate pad;
coupling a second semiconductor die with the substrate, the second semiconductor die implementing a second field-effect transistor with a gate terminal accessible by a second gate pad;
coupling a first resistor to the first gate pad and a second resistor to the second gate pad; and
coupling a conductive element with the first resistor on the first gate pad and with the second resistor on the second gate pad.

19. The method of claim 18, further comprising:
coupling a leadframe to the substrate, the leadframe including a plurality of leads; and
at least partially encapsulating, within a molding compound, the substrate, the first semiconductor die, the second semiconductor die, the conductive element, the first resistor, the second resistor, and the plurality of leads.

20. The method of claim 18, wherein:
the substrate is implemented by a direct-bonded metal (DBM) substrate having a patterned layer of metal bonded to a ceramic substrate;
the first semiconductor die and the second semiconductor die are silicon carbide (SiC) dies fabricated using a SiC semiconductor; and
the first field-effect transistor and the second field-effect transistor are power metal-oxide-semiconductor field-effect transistors (MOSFETs).
